(19) United States
(12) Patent Application Publication
(10) Pub. No.: US 2024/0405747 A1
(43) Pub. Date: Dec. 5, 2024

(54) RESONATOR AND PHASE SHIFTER SHUNT HYBRID STRUCTURE FOR EXTRACTOR DESIGN

(71) Applicant: Skyworks Solutions, Inc., Irvine, CA (US)

(72) Inventors: Chuan Shi, San Jose, CA (US); Bo Pan, Irvine, CA (US)

(21) Appl. No.: 18/676,262

(22) Filed: May 28, 2024

Related U.S. Application Data
(60) Provisional application No. 63/505,183, filed on May 31, 2023.
(60) Provisional application No. 63/505,153, filed on May 31, 2023.

(51) Int. Cl. H03H 9/60; H03H 9/54; H03H 9/72

(52) U.S. Cl. CPC H03H 9/605; H03H 9/542; H03H 9/725

(57) ABSTRACT

A frequency extraction filter is disclosed. The frequency extraction filter can include a resonator that is coupled to a first node, and a phase shifter that is connected to the resonator in series. The phase shifter is coupled to a second node such that the resonator and the phase shifter are positioned between the first and second nodes. Impedance between the first and second nodes has an order of four or more.

### INCORPORATION BY REFERENCE TO ANY PRIORITY APPLICATIONS

Any and all applications for which a foreign or domestic priority claim is identified in the Application Data Sheet as filed with the present application, including U.S. Provisional Patent Application No. 63/505,183, filed May 31, 2023, titled “EXTRACTOR DESIGN WITH RESONATOR AND PHASE SHIFTER SERIES HYBRID STRUCTURE,” and U.S. Provisional Patent Application No. 63/505,153, filed May 31, 2023, titled “RESONATOR AND PHASE SHIFTER SHUNT HYBRID STRUCTURE FOR EXTRACTOR DESIGN,” are hereby incorporated by reference under 37 CFR 1.57 in their entirety.

### BACKGROUND

### Field

Embodiments of the present disclosure relate to hybrid extractor designs, and in particular, to hybrid extractor designs that include a resonator and a phase shifter.

### Description of Related Technology

A radio frequency (RF) communication system can include a transceiver, a front end, and one or more antennas for wirelessly transmitting and/or receiving signals. The front end can include low noise amplifier(s) for amplifying relatively weak signals received via the antenna(s) and power amplifier(s) for boosting signals for transmission via the antenna(s).

Examples of RF communication systems include, but are not limited to, mobile phones, tablets, base stations, network access points, customer-premises equipment (CPE), laptops, and wearable electronics. RF signals have a frequency in the range from about 30 kHz to 300 GHz, for instance, in the range of about 400 MHz to about 7.125 GHz for Frequency Range 1 (FR1) of the Fifth Generation (5G) communication standard or in the range of about 24.250 GHz to about 71.000 GHz for Frequency Range 2 (FR2) of the 5G communication standard.

### SUMMARY

The innovations described in the claims each have several aspects, no single one of which is solely responsible for its desirable attributes. Without limiting the scope of the claims, some prominent features of this disclosure will now be briefly described.

In some aspects, the techniques described herein relate to a frequency extraction filter including: a resonator coupled to a first node; and a phase shifter connected to the resonator in series, the phase shifter coupled to a second node such that the resonator and the phase shifter are positioned between the first and second nodes, impedance between the first and second nodes has an order of four or more.

In some embodiments, the techniques described herein relate to a frequency extraction filter wherein the impedance between the first and second nodes at least two notches for rejections.

In some embodiments, the techniques described herein relate to a frequency extraction filter wherein the phase shifter is a passive phase shifter.

In some embodiments, the techniques described herein relate to a frequency extraction filter wherein the passive phase shifter is a transmission line, a high pass network phase shifter, a low pass network phase shifter, an all pass network phase shifter, or a reflection type phase shifter.

In some embodiments, the techniques described herein relate to a frequency extraction filter wherein the phase shifter is an active phase shifter.

In some embodiments, the techniques described herein relate to a frequency extraction filter wherein the active phase shifter is a vector based phase shifter.

In some embodiments, the techniques described herein relate to a frequency extraction filter wherein the impedance between the first and second nodes is controlled such that the phase shifter introduces at least one reflection zero and at least one transmission zero.

In some embodiments, the techniques described herein relate to a frequency extraction filter wherein locations of the at least one transmission zero and the at least one reflection zero are set so as to improve insertion loss and rejection.

In some embodiments, the techniques described herein relate to a frequency extraction filter wherein the resonator and the phase shifter together defines a first hybrid structure, and the frequency extraction filter further including a second resonator and a second phase shifter together defining a second hybrid structure, wherein the first and second hybrid structures are coupled to one another.

In some embodiments, the techniques described herein relate to a frequency extraction filter further including a third resonator and a third phase shifter together defining a third hybrid structure, wherein the first, second, and third hybrid structures are electrically coupled.

In some embodiments, the techniques described herein relate to a frequency extraction filter wherein the second resonator and the second phase shifter are connected in series, and the third resonator and the third phase shifter are connected in parallel.

In some aspects, the techniques described herein relate to a series hybrid extractor structure including: a resonator coupled to a first node; and a phase shifter connected to the resonator in series, the phase shifter coupled to a second node such that the resonator and the phase shifter are positioned between the first and second nodes, a frequency response of the series hybrid extractor structure includes at least two reflection zeros and at least two transmission zeros.

In some embodiments, the techniques described herein relate to a series hybrid extractor structure wherein the phase shifter is a passive phase shifter.

In some embodiments, the techniques described herein relate to a series hybrid extractor structure wherein the passive phase shifter is a transmission line, a high pass network phase shifter, a low pass network phase shifter, an all pass network phase shifter, or a reflection type phase shifter.

In some embodiments, the techniques described herein relate to a series hybrid extractor structure wherein the phase shifter is an active phase shifter.

In some embodiments, the techniques described herein relate to a series hybrid extractor structure wherein the active phase shifter is a vector based phase shifter.

In some aspects, the techniques described herein relate to a wireless communication device including: a frequency extraction filter including a resonator coupled to a first node and a phase shifter connected to the resonator in series, the phase shifter coupled to a second node such that the resonator and the phase shifter are positioned between the first and second nodes, impedance between the first and second nodes has an order of four or more; and an antenna coupled to the first node.

In some embodiments, the techniques described herein relate to a wireless communication device wherein the resonator and the phase shifter together defines a first hybrid structure, and the frequency extraction filter further including a second resonator and a second phase shifter together defining a second hybrid structure, wherein the first and second hybrid structures are coupled to one another.

In some embodiments, the techniques described herein relate to a wireless communication device further including a third resonator and a third phase shifter together defining a third hybrid structure, wherein the first, second, and third hybrid structures are electrically coupled.

In some embodiments, the techniques described herein relate to a wireless communication device wherein the second resonator and the second phase shifter are connected in series, and the third resonator and the third phase shifter are connected in parallel.

In some aspects, the techniques described herein relate to a frequency extraction filter including: a resonator coupled to a first node; and a phase shifter connected to the resonator in parallel, the phase shifter coupled to a second node such that the resonator and the phase shifter are positioned between the first and second nodes, impedance between the first and second nodes has an order of five or more.

In some embodiments, the techniques described herein relate to a frequency extraction filter wherein the impedance between the first and second nodes at least two notches for rejections.

In some embodiments, the techniques described herein relate to a frequency extraction filter wherein the phase shifter is a passive phase shifter.

In some embodiments, the techniques described herein relate to a frequency extraction filter wherein the passive phase shifter is a transmission line, a high pass network phase shifter, a low pass network phase shifter, an all pass network phase shifter, or a reflection type phase shifter.

In some embodiments, the techniques described herein relate to a frequency extraction filter wherein the phase shifter is an active phase shifter.

In some embodiments, the techniques described herein relate to a frequency extraction filter wherein the active phase shifter is a vector based phase shifter.

In some embodiments, the techniques described herein relate to a frequency extraction filter wherein the impedance between the first and second nodes is controlled such that the phase shifter introduces at least one reflection zero and at least one transmission zero.

In some embodiments, the techniques described herein relate to a frequency extraction filter wherein locations of the at least one transmission zero and the at least one reflection zero are set so as to improve insertion loss and rejection.

In some embodiments, the techniques described herein relate to a frequency extraction filter wherein the resonator and the phase shifter together defines a first hybrid structure, and the frequency extraction filter further including a second resonator and a second phase shifter together defining a second hybrid structure, wherein the first and second hybrid structures are coupled to one another.

In some embodiments, the techniques described herein relate to a frequency extraction filter further including a third resonator and a third phase shifter together defining a third hybrid structure, wherein the first, second, and third hybrid structures are electrically coupled.

In some embodiments, the techniques described herein relate to a frequency extraction filter wherein the second resonator and the second phase shifter are connected in series, and the third resonator and the third phase shifter are connected in series.

In some aspects, the techniques described herein relate to a shunt hybrid extractor structure including: a resonator coupled to a first node; and a phase shifter connected to the resonator in parallel, the phase shifter coupled to a second node such that the resonator and the phase shifter are positioned between the first and second nodes, a frequency response of the shunt hybrid extractor structure includes at least three reflection zeros and at least two transmission zeros.

In some embodiments, the techniques described herein relate to a shunt hybrid extractor structure wherein the phase shifter is a passive phase shifter.

In some embodiments, the techniques described herein relate to a shunt hybrid extractor structure wherein the passive phase shifter is a transmission line, a high pass network phase shifter, a low pass network phase shifter, an all pass network phase shifter, or a reflection type phase shifter.

In some embodiments, the techniques described herein relate to a shunt hybrid extractor structure wherein the phase shifter is an active phase shifter.

In some embodiments, the techniques described herein relate to a shunt hybrid extractor structure wherein the active phase shifter is a vector based phase shifter.

In some aspects, the techniques described herein relate to a wireless communication device including: a frequency extraction filter including a resonator coupled to a first node and a phase shifter connected to the resonator in parallel, the phase shifter coupled to a second node such that the resonator and the phase shifter are positioned between the first and second nodes, impedance between the first and second nodes has an order of five or more; and an antenna coupled to the first node.

In some embodiments, the techniques described herein relate to a wireless communication device wherein the resonator and the phase shifter together defines a first hybrid structure, and the frequency extraction filter further including a second resonator and a second phase shifter together defining a second hybrid structure, wherein the first and second hybrid structures are coupled to one another.

In some embodiments, the techniques described herein relate to a wireless communication device further including a third resonator and a third phase shifter together defining a third hybrid structure, wherein the first, second, and third hybrid structures are electrically coupled.

In some embodiments, the techniques described herein relate to a wireless communication device wherein the second resonator and the second phase shifter are connected in series, and the third resonator and the third phase shifter are connected in series.

The present disclosure relates to U.S. patent application Ser. No. ______ [Attorney Docket SKYWRKS. 1467A1], titled “EXTRACTOR DESIGN WITH RESONATOR AND PHASE SHIFTER SERIES HYBRID STRUCTURE,” filed on even date herewith, the entire disclosure of which is hereby incorporated by reference herein.

### BRIEF DESCRIPTION OF THE DRAWINGS

Embodiments of this disclosure will now be described, by way of non-limiting example, with reference to the accompanying drawings.

FIG. 1 shows a block diagram of an example extractor design.

FIG. 2 is a graph showing an example specification of the extractor design of FIG. 1.

FIG. 3 is a schematic diagram of an extractor that has a series hybrid structure according to an embodiment.

FIG. 4 is a graph showing simulated in a frequency response of the extractor of FIG. 3.

FIG. 5A is a graph showing simulated frequency responses of an acoustic resonator alone, the extractor of FIG. 3, and a parallel inductors (L) capacitors (C) tank between a frequency range of 0 to 6 GHz.

FIG. 5B is a graph showing simulated frequency responses of the acoustic resonator alone and the extractor of FIG. 3 between a frequency range of 1.4 GHz to 3 GHz.

FIG. 6 is a schematic diagram of an extractor that has a shunt or parallel hybrid structure according to an embodiment.

FIG. 7 is a graph showing simulated in a frequency response of the extractor of FIG. 6.

FIG. 8A is a graph showing simulated frequency responses of an acoustic resonator alone, the extractor of FIG. 6, and a parallel inductors (L) capacitors (C) tank between a frequency range of 0 to 6 GHz.

FIG. 8B is a graph showing simulated frequency responses of the acoustic resonator alone and the extractor of FIG. 6 between a frequency range of 1.4 GHz to 3 GHz.

FIG. 9A is a schematic diagram showing an extractor design having a t-structure including acoustic resonators and lumped elements.

FIG. 9B is a schematic diagram showing an extractor design according to an embodiment.

FIG. 10A is a graph showing simulated frequency responses of the extractor design of FIG. 9A and the extractor design of FIG. 9B between a frequency range of 0 to 6 GHz.

FIG. 10B is a graph showing a portion of the simulated frequency responses of FIG. 10A between a frequency range of 1.4 GHz to 2.7 GHz and −50 dB to 0 dB.

FIG. 10C is a graph showing a portion of the simulated frequency responses of FIG. 10A between a frequency range of 1.4 GHz to 2.7 GHz and −1 dB to 0 dB.

FIG. 11A is a Smith chart showing contour responses of the extractor designs of FIGS. 9A and 9B at an input side for a frequency range between 1.7 GHz and 2.7 GHz.

FIG. 11B is a Smith chart showing contour responses of the extractor designs of FIGS. 9A and 9B at an output side for a frequency range between 1.7 GHz and 2.7 GHz.

FIG. 11C is a Smith chart showing contour responses of the extractor designs of FIGS. 9A and 9B at an input side for a frequency range between 1.4 GHz and 1.5 GHz.

FIG. 11D is a Smith chart showing contour responses of the extractor designs of FIGS. 9A and 9B at an output side for a frequency range between 1.4 GHz and 1.5 GHz.

FIGS. 12A and 12B are schematic diagrams of example high/low pass network phase shifters.

FIGS. 12C and 12D are schematic diagrams of example all pass network phase shifters.

FIG. 12E is a schematic diagram of an example reflection type phase shifter on a coupling structure.

FIG. 13 is schematic diagrams of an example vector based phase shifter.

FIGS. 14, 15, and 16 are schematic block diagrams of illustrative packaged modules according to certain embodiments.

FIG. 17 is a schematic diagram of one embodiment of a mobile device.

### DETAILED DESCRIPTION OF CERTAIN EMBODIMENTS

The following detailed description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Radio frequency (RF) communication systems and/or devices, such as mobile phones, tablets, base stations, network access points, customer-premises equipment (CPE), laptops, and wearable electronics, can be used for transmitting and/or receiving signals of a wide range of frequencies. For example, an RF communication system can be used to wirelessly communicate RF signals in a frequency range of about 30 kHz to 300 GHz, such as in the range of about 400 MHz to about 7.125 GHz for Frequency Range 1 (FR1) of the Fifth Generation (5G) communication standard or in the range of about 24.25 GHz to about 71 GHz for Frequency Range 2 (FR2) of the 5G communication standard.

An antenna-plexer or antenna-multiplexer is a type of electronic device that allows multiple antennas to share a common radio frequency (RF) feedline. The antenna-plexer can be designed to combine or separate multiple RF signals from a plurality of antennas. An antenna-plexer can include a series of switches, filters, and amplifiers that are used to combine or separate the RF signals from the plurality of antennas. Depending on the specific design, an antenna-plexer may also include signal conditioning, impedance matching, or other signal processing components.

A design specification may call for a wideband frequency extractor with low insertion loss and high rejection. A wideband frequency extractor can be used to extract specific frequency components from a broadband signal. For example, wideband frequency extractors can be used to analyze and process complex acoustic signals. The extractors can be used to isolate specific frequency components, which can be used for further analysis or processing.

One known method for wideband frequency extraction is to use band-pass filters, which are designed to pass only a narrow frequency range of the input signal. Another known method for wideband frequency extraction is to use band-stop ladder structures. To obtain a relatively high bandwidth to meet the desired rejections in the very close vicinity of the in-band (e.g., right above and/or below the in-band frequency), traditional inductor (L)-capacitor (C) resonators or LC topologies can be used for the filter design. For a narrow extractor design, the acoustic resonator can be utilized. For example, a band-stop filter and an LC elliptic filter can define an extractor. The band-stop filter can be used to attenuate or block unwanted frequencies within a specific frequency band, while the LC elliptic filter can be used to selectively pass or reject frequencies within the same band. Such a stop-band LC elliptic combined filter can provide a relatively high quality factor (Q), and a sharp and deep rejection in the frequency extraction range. Frequencies away from the resonance and anti-resonance frequencies can provide wide pass band with good insertion loss. However, there can be trade-offs, for example, between the insertion loss (e.g., the amount of signal power that is lost as the signal passes through the filter) and rejection (e.g., the amount of attenuation or blocking of the unwanted frequencies), especially with more stringent rejection requirements.

A low order (e.g., lower than order of 3) acoustic resonator ladder structure can be used as band-stop design for frequency extraction to minimize the trade-off between the insertion loss and the rejection. The low order acoustic resonator ladder structure can include less components and hence less spacing is occupied and less loss is introduced by LC components. A low order acoustic resonator ladder structure can reduce loss in the pass band, but the low order acoustic resonator ladder structure also reduces the rejection outside the pass band. The low order acoustic resonator ladder structure may also cause sparse contour which can be detrimental to insertion loss especially when the bandwidth is high.

Various embodiments disclosed herein relate to a hybrid structure of acoustic resonator and an electromagnetic (EM) phase shifter. The EM phase shifter can be coupled to the acoustic resonator by either a series connection or a parallel connection as a building block low order frequency extraction ladder filter design.

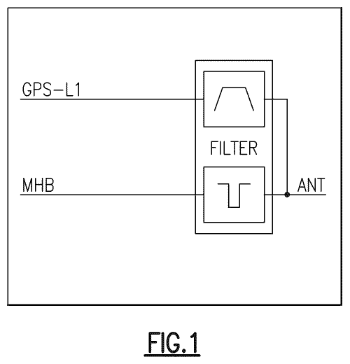

FIG. 1 shows a block diagram of an example extractor design. The extractor of FIG. 1 can handle frequencies from a low-mid band (LMB) (e.g., 1427 MHz to 1517 MHz), a mid-high band (MHB) (e.g., 1700 MHz to 2690 MHz), to, for example, a global positioning system (GPS) LI band (e.g., 1571 MHz to 1606 MHz).

FIG. 2 is a graph showing an example specification of the extractor design of FIG. 1. The graph of FIG. 2 shows the S21 scattering parameter that represents the transmission of acoustic energy through the extractor design in decibels (dB). The x-axis shows the frequency in giga-hertz (GHz). The graph indicates that rejection of about at least-25 dB is desired within the vicinity of the in-band frequencies of the extractor. The specification can call for the extractor design to have relatively low insertion loss between about 1.4 GHz to 1.5 GHz and about 1.7 GHz and 2.7 GHz. The GPS-LI band can be extracted from the frequency range of 1.4 GHz to 2.7 GHz. The graph can indicate that the rejection in low band (LB) frequency (e.g., less than 1.4 GHz), NR77 band (e.g., 3.3 GHz to 4.2 GHz), and NR79 band (e.g., 4.4 GHz to 5 GHz) are also stringent. This rejection specification will have more trade-off influence in the insertion loss from 1.4 GHz to 2.7 GHz.

Hybrid structures that include an acoustic resonator and a phase shifter disclosed herein can provide improved rejection and insertion loss. A hybrid structure can be a series hybrid structure or a shunt or parallel hybrid structure. In the series hybrid structure, phase shifting properties can be tuned by different characteristic impedance of the transmission line, and/or by phase shifting between an open node and a signal connection node of the transmission line. The parallel hybrid structure can be formed by a phase shifter represented by a transmission line. The phase shifting magnitude and the characteristic impedance can be another tuning parameters, and the phase shifter can be shunted with an acoustic resonator. In various embodiments disclosed herein, a resonator can serve to form extractor frequencies for an extractor, and a phase shifter can serve as a wider resonator that provides resonance and anti-resonance for rejection and insertion loss improvements.

Both the series and shunt hybrid structures can provide additional transmission zeros and additional reflection zeros in an extractor design. The acoustic resonator implemented in the hybrid structure will have a degree of freedom of area and resonator frequency. The phase shifter can choose the phase shifting value and characteristic impedance as a degree of freedom. Although the embodiments disclosed herein may be represented by a transmission line, the phase shifter may be implemented as a lumped element, a coupled line or balun type, or an active shifter such as a switch type phase shifter or a vector-based shifter.

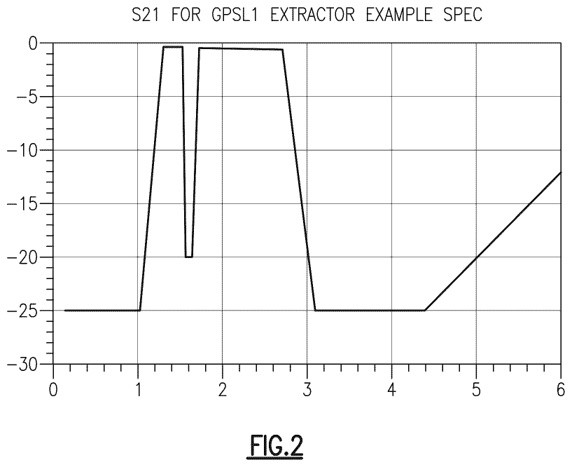

FIG. 3 is a schematic diagram of an extractor 1 that has a series hybrid structure according to an embodiment. The extractor 1 can include an acoustic resonator 10 and a phase shifter 12 connected in series between nodes P1, P2. In some embodiments, the node P1 can be an input node and the node P2 can be an output node. In some embodiments, the resonator 10 can be a surface acoustic wave (SAW) resonator or a bulk acoustic wave (BAW) resonator.

When the phase shifter 12 is represented by a transmission line as shown in FIG. 3, an impedance between the nodes P1, P2 can be modeled by the following equation

$$Z = {Z}_{0} \frac{1 + {e}^{- j \frac{w}{2 {f}_{0}}}}{1 - {e}^{- j \frac{w}{2 {f}_{0}}}} + \frac{( 1 - \frac{{w}^{2}}{{w}_{r}^{2}} )}{( 1 - \frac{{w}^{2}}{{w}_{a}^{2}} )} \frac{1}{{jwC}_{p}} . \qquad ( Equation 1 )$$

Z₀ is a characteristic impedance of the phase shifter 12; f₀ is a frequency where the phase shifter 12 has 90 degrees phase shifting; w is an angular frequency; wᵣ is an angular resonance frequency of the acoustic resonator 10; wₐ is an angular anti-resonance frequency of the acoustic resonator; and Cₚ is a capacitance of the acoustic resonator which is related to an acoustic area. In an extractor filter, the impedance plays a crucial role in determining the filter's frequency response and its ability to extract a specific frequency band from a complex signal. In some embodiments, a frequency of the resonator 10 and/or a phase shifter variation of the phase shifter 12 can be modified to provide desired impedance between the nodes P1, P2. The phase shifter 12 can enable easier optimization than conventional design that does not include a phase shifter.

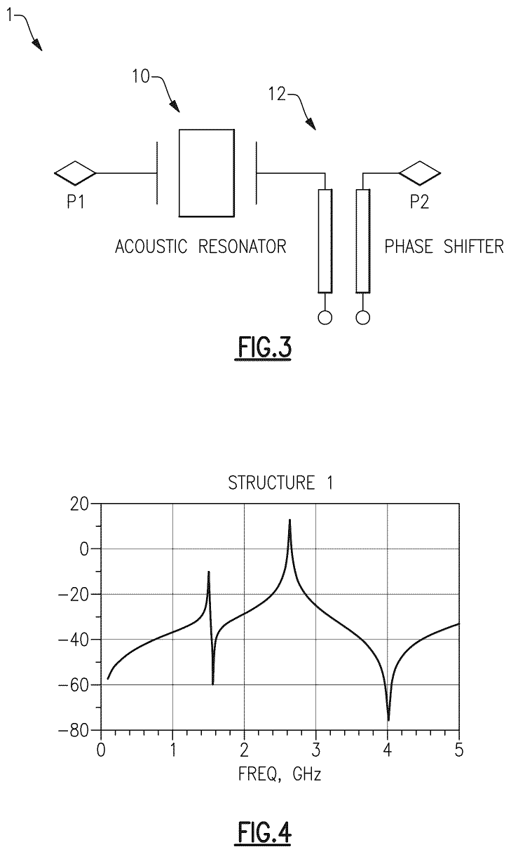

FIG. 4 is a graph showing a simulated frequency response of the extractor 1 of FIG. 3. The graph shows two peaks and two valleys. The two peaks indicate low impedance values and the two valleys indicate high impedance values. High impedance value locations/areas can be used as notches for rejection, and low impedance regions can be used as insertion loss improvement for wide band insertion loss.

As indicated in Equation 1 shown above, a basic working principle is that the capacitive loading after connection with a phase shifter is a rotation on a Smith chart. With different rotations on the Smith chart, a different frequency response can be provided. The rotation is a transformation that involves rotating the chart about its center. The rotation angle is usually specified in degrees and can be positive or negative. The rotation on the Smith chart can be useful for various radio frequency (RF) design applications, such as impedance matching and the analysis of transmission line problems. The gamma (the reflection coefficient, which is the ratio of the reflected voltage wave to the incident voltage wave at a point along a transmission line) can be extended by the phase shifter and the loading together with the acoustic resonator such that the nodes P1, P2 can form an average wide band frequency range for resonance and anti-resonance. Based on this principle, the phase shifter 12 implementation may not be limited to a transmission line. For example, the phase shifter 12 may be implemented as a passive shifter such as a lumped element, a coupled line or balun type, or an active shifter such as a switch type phase shifter or a vector-based shifter.

By combining the resonator 10 with the phase shifter 12 and selecting or optimizing the impedance, locations of the additional transmission zeros or reflection zeros can be controlled. Therefore, the extractor 1 can be optimized (e.g., proper selection of the parameters of Equation 1 shown above) to provide additional transmission zero(s) and additional reflection zero(s) that improves the insertion loss and rejection.

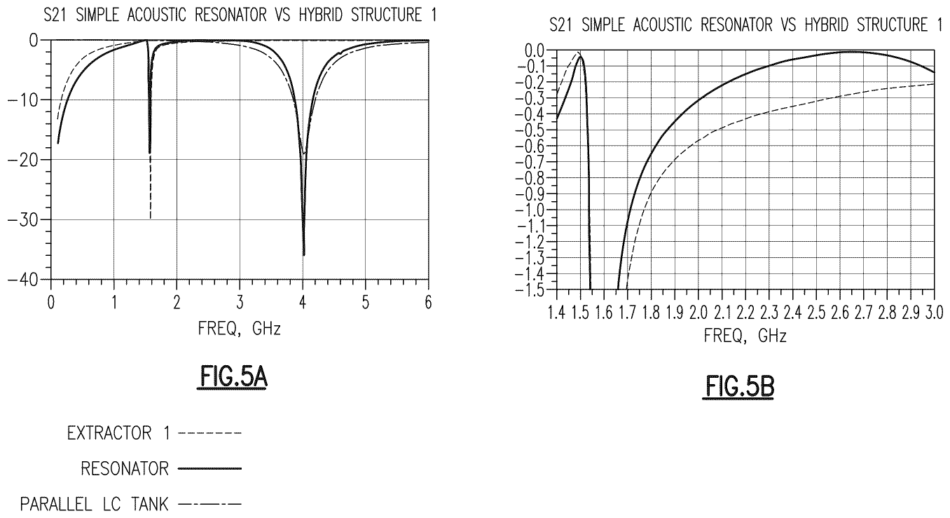

FIG. 5A is a graph showing simulated frequency responses of an acoustic resonator alone, the extractor 1 of FIG. 3, and a parallel inductor (L)-capacitor (C) tank between a frequency range of 0 to 6 GHz. FIG. 5B is a graph showing simulated frequency responses of the acoustic resonator alone and the extractor 1 of FIG. 3 between a frequency range of 1.4 GHz to 3 GHz. The graphs of FIGS. 5A and 5B indicate that the extractor 1 can provide one (1) additional reflection zero in a relatively high frequency that can be used as a rejection tuning node and one (1) additional transmission zero in a relatively high frequency. Therefore, as compared to the acoustic resonator alone or the LC tank, the extractor 1 can provide less trade-off between insertion loss and rejection and improve the insertion loss and rejection. The impedance of the extractor 1 can have an order of four (4) or more.

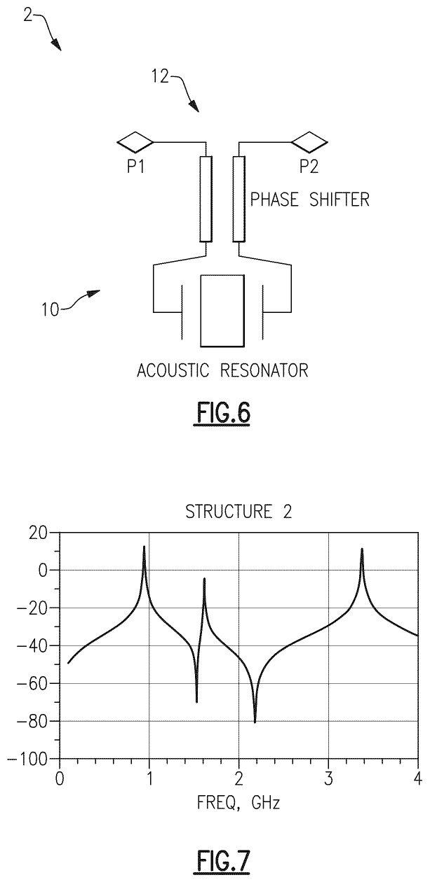

FIG. 6 is a schematic diagram of an extractor 2 that has a shunt or parallel hybrid structure according to an embodiment. The extractor 2 can include an acoustic resonator 10 and a phase shifter 12 connected in parallel between nodes P1, P2. In some embodiments, the node P1 can be an input node and the node P2 can be an output node. When the phase shifter 12 is represented by a transmission line as shown in FIG. 6, an impedance between the nodes P1, P2 can be modeled by the following equation

$$Z = \frac{( 1 - \frac{{w}^{2}}{{w}_{r}^{2}} ) - {Z}_{0} ( 1 - \frac{{w}^{2}}{{w}_{a}^{2}} ) {wC}_{p} * tan ( \frac{w}{4 {f}_{0}} )}{{jwC}_{p} {Z}_{0} ( 1 - \frac{{w}^{2}}{{w}_{a}^{2}} ) + j ( 1 - \frac{{w}^{2}}{{w}_{r}^{2}} ) * tan ( \frac{w}{4 {f}_{0}} )} . \qquad ( Equation 2 )$$

Z₀ is a characteristic impedance of the phase shifter 12; f₀ is a frequency where the phase shifter 12 has 90 degrees phase shifting; w is an angular frequency; wᵣ is an angular resonance frequency of the acoustic resonator 10; wₐ is an angular anti-resonance frequency of the acoustic resonator; and Cₚ is a capacitance of the acoustic resonator which is related to an acoustic area. Therefore, when the angular frequency w is small (e.g., significantly smaller than the angular resonance frequency wᵣ), the impedance Z can have a zero; and when the angular frequency w is large (e.g., significantly larger than the angular inti-resonance frequency wₐ), the impedance Z can have one zero and one pole.

FIG. 7 is a graph showing simulated in a frequency response of the extractor 2 of FIG. 6. The graph of FIG. 7 shows three resonance frequencies, three reflection zeros, two anti-resonance frequencies, and two transmission zeros. The gamma (the reflection coefficient, which is the ratio of the reflected voltage wave to the incident voltage wave at a point along a transmission line) after the phase shifter loading can show a frequency dependent resonance frequency that can be shifted between the resonance frequencies formed by the phase shifter 12.

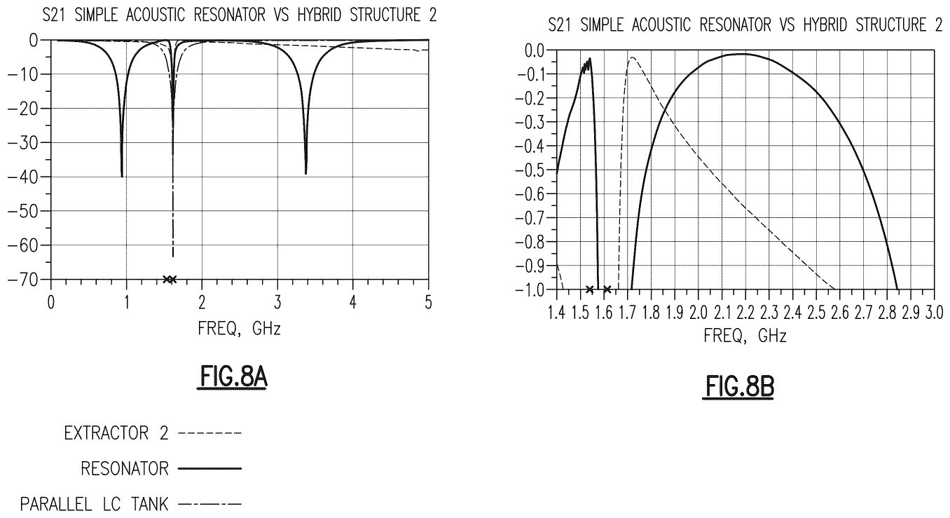

FIG. 8A is a graph showing simulated frequency responses of an acoustic resonator alone, the extractor 2 of FIG. 6, and a parallel inductor (L)-capacitor (C) tank between a frequency range of 0 to 6 GHz. FIG. 8B is a graph showing simulated frequency responses of the acoustic resonator alone and the extractor 2 of FIG. 6 between a frequency range of 1.4 GHz to 3 GHz. The graphs of FIGS. 5A and 5B indicate that the extractor 2 can provide one (1) additional reflection zero in a relatively high frequency that can be used as a rejection tuning node, one (1) additional transmission zero in a relatively high frequency, and one (1) additional transmission zero in a relatively low frequency which can be used to fulfill a low frequency rejection requirement. The two reflection zeros can be served as rejection poles below and above a desired frequency range. The reflection zero of the extractor 2 shown in FIG. 8B can be tuned by selecting different parameters. A difference between the resonance frequency and an anti-resonance frequency of the resonator are determined by an electromechanical coupling coefficient (kt²) and may not be tuned. However, in the extractor 2, a difference between the additional reflection zero and anti-resonance frequency can be tuned by using different parameters. Therefore, as compared to the acoustic resonator alone or the LC tank, the extractor 2 can provide less trade-off between insertion loss and rejection and improve the insertion loss and rejection. The impedance of the extractor 2 can have an order of five (5) or more.

In some embodiments, two or more extractors can be implemented in a filter. For example, the extractor 1 that has the series hybrid structure and the extractor 2 that has the shunt or parallel hybrid structure can be combined in a filter design.

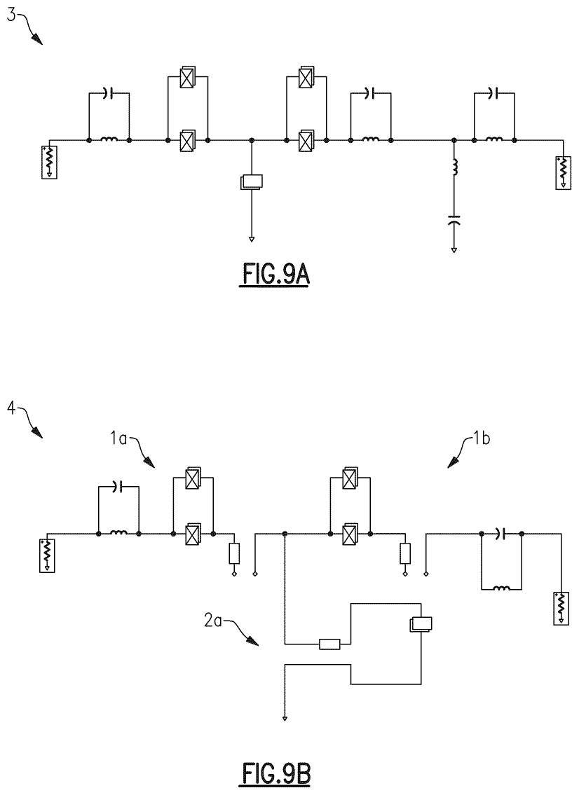

FIG. 9A is a schematic diagram showing an extractor design 3 having a t-structure including acoustic resonators and lumped elements. FIG. 9B is a schematic diagram showing an extractor design 4 according to an embodiment. The extractor design 4 includes two series hybrid structures 1a, 1b and one shunt hybrid structure 2a. The series hybrid structures 1a, 1b can each include the resonator 10 and the phase shifter 12 (see FIGS. 3 and 6) that are connected in series, and the shunt hybrid structure 2a can include the resonator 10 and the phase shifter 12 that are connected in parallel. The series hybrid structures 1a, 1b and the shunt hybrid structure 2a can be arranged in a three-order t-ladder design.

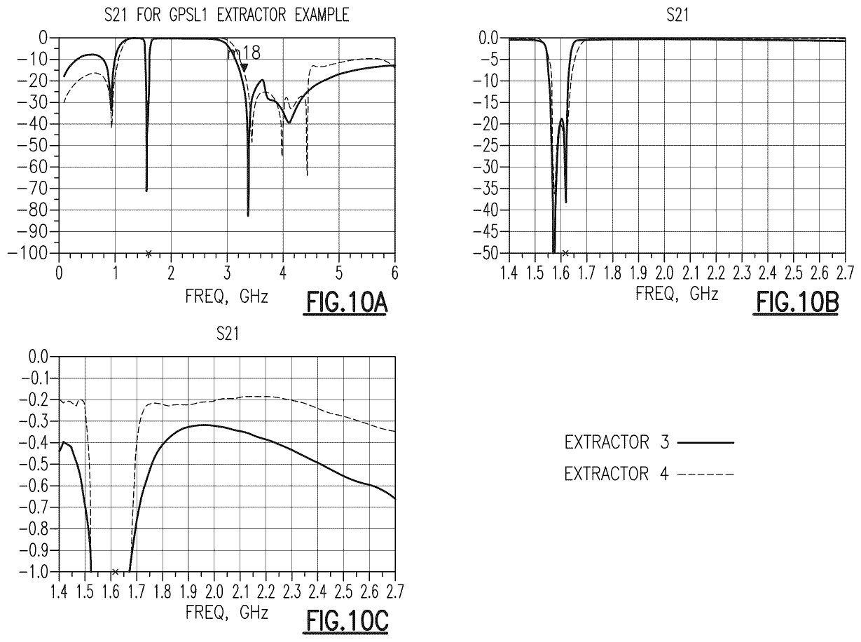

FIG. 10A is a graph showing simulated frequency responses of the extractor design 3 of FIG. 9A and the extractor design 4 of FIG. 9B between a frequency range of 0 to 6 GHz. FIG. 10B is a graph showing a portion of the simulated frequency responses of FIG. 10A between a frequency range of 1.4 GHz to 2.7 GHz and −50 dB to 0 dB. FIG. 10C is a graph showing a portion of the simulated frequency responses of FIG. 10A between a frequency range of 1.4 GHz to 2.7 GHz and −1 dB to 0 dB.

The graphs of FIGS. 10A to 10C indicate that the frequency response of the extractor design 4 has an improved rejection for a relatively low frequency and improved insertion loss between about 1.7 GHz and 2.7 GHz and between about 1.4 GHz to 1.49 GHz as compared to the frequency response of the extractor design 3, and similar performance at high frequency and extraction frequency as the extractor design 3.

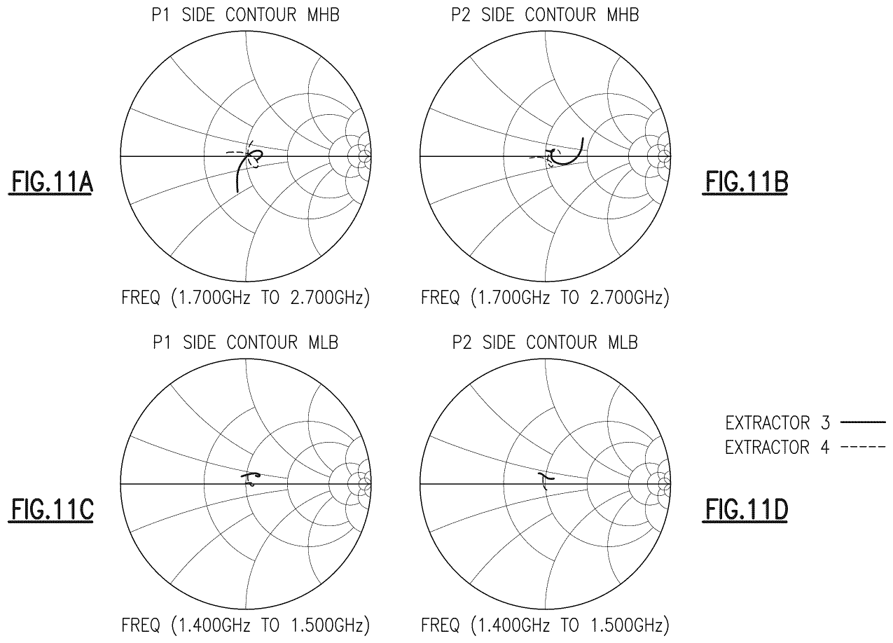

FIG. 11A is a Smith chart showing contour responses of the extractor designs 3, 4 of FIGS. 9A and 9B at an input side for a frequency range between 1.7 GHz and 2.7 GHz. FIG. 11B is a Smith chart showing contour responses of the extractor designs 3, 4 of FIGS. 9A and 9B at an output side for a frequency range between 1.7 GHz and 2.7 GHz. FIG. 11C is a Smith chart showing contour responses of the extractor designs 3, 4 of FIGS. 9A and 9B at an input side for a frequency range between 1.4 GHz and 1.5 GHz. FIG. 11D is a Smith chart showing contour responses of the extractor designs 3, 4 of FIGS. 9A and 9B at an output side for a frequency range between 1.4 GHz and 1.5 GHz.

FIGS. 11A to 11D show that the contours of the extractor design 4 are significantly tighter than the contours of the extractor design 3 (e.g., from 2.149 to 1.647 in FIG. 11A, from 1.876 to 1.649 in FIG. 11B, from 1.246 to 1.242 in FIG. 11C, and from 1.292 to 1.24 in FIG. 11D). FIGS. 11A to 11D can indicate that a higher order nature of the hybrid structure of the extractor design 4 provides more power transmitted through between the input and output sides than the extractor design 3, and provides the tighter contours and improved insertion loss.

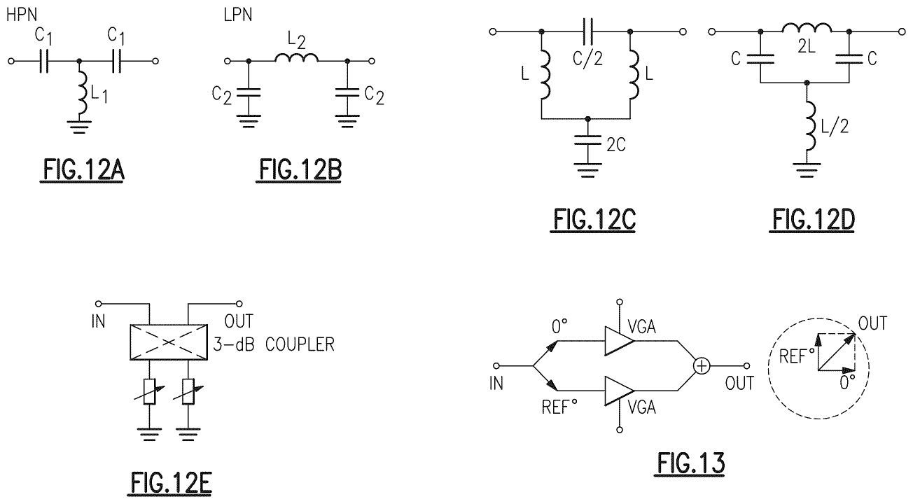

As noted above, the phase shifter 12 may not be limited to a transmission line, and the phase shifter 12 may be implemented in various ways. In some embodiments, the phase shifter 12 can be a passive phase shifter or an active phase shifter. FIGS. 12A to 13B are schematic diagrams of example phase shifter designs that can be implemented in the hybrid structures disclosed herein. FIGS. 12A and 12B are schematic diagrams of example high/low pass network phase shifters. FIGS. 12C and 12D are schematic diagrams of example all pass network phase shifters. FIG. 12E is a schematic diagram of an example reflection type phase shifter on a coupling structure. FIG. 13 is a schematic diagram of an example vector-based phase shifter.

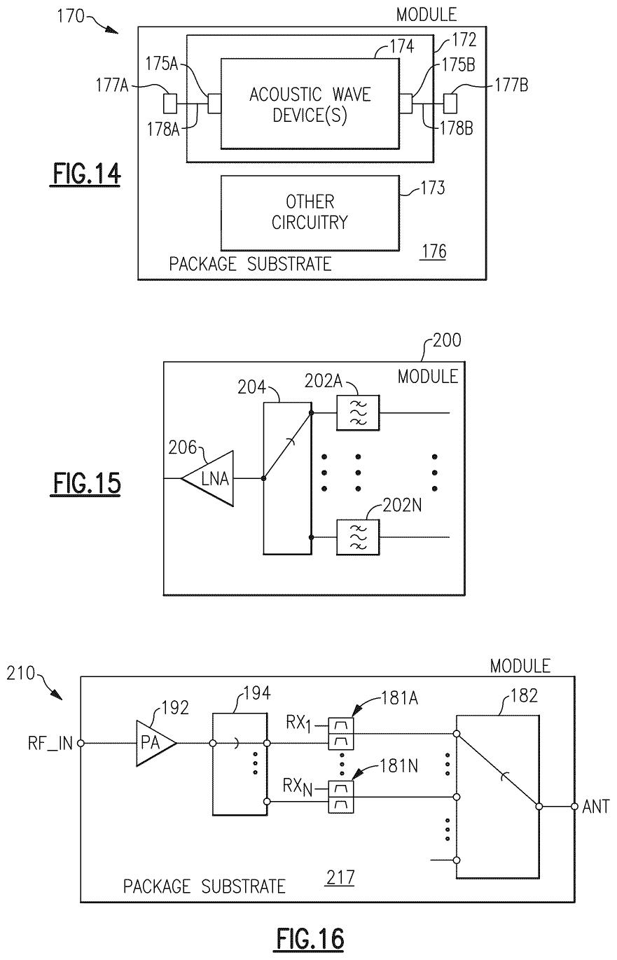

Extractors with a hybrid structure disclosed herein can be implemented in a variety of packaged modules. Some example packaged modules will now be disclosed in which any suitable principles and advantages of the extractors with a hybrid structure disclosed herein can be implemented. The example packaged modules can include a package that encloses the illustrated circuit elements. A module that includes a radio frequency component can be referred to as a radio frequency module. The illustrated circuit elements can be disposed on a common packaging substrate. The packaging substrate can be a laminate substrate, for example. FIGS. 14 to 16 are schematic block diagrams of illustrative packaged modules according to certain embodiments. Any suitable combination of features of these packaged modules can be implemented with each other.

FIG. 14 is a schematic diagram of a radio frequency module 170 that includes an acoustic wave component 172 according to an embodiment. The illustrated radio frequency module 170 includes the acoustic wave component 172 and other circuitry 173. The acoustic wave component 172 can include acoustic wave devices 174 of a filter, for example. The acoustic wave devices 174 can be BAW devices in certain applications.

The acoustic wave component 172 shown in FIG. 14 includes acoustic wave devices 174 and terminals 175A and 175B. The terminals 175A and 174B can serve, for example, as an input contact and an output contact. Although two terminals are illustrated, any suitable number of terminals can be implemented for a particular application. The acoustic wave component 172 and the other circuitry 173 are on a common packaging substrate 176 in FIG. 14. The packaging substrate 176 can be a laminate substrate. The terminals 175A and 175B can be electrically connected to contacts 177A and 177B, respectively, on the packaging substrate 176 by way of electrical connectors 178A and 178B, respectively. The electrical connectors 178A and 178B can be bumps or wire bonds, for example.

The other circuitry 173 can include any suitable additional circuitry. For example, the other circuitry can include one or more radio frequency amplifiers (e.g., one or more power amplifiers and/or one or more low noise amplifiers), one or more radio frequency switches, one or more additional filters, one or more RF couplers, one or more delay lines, one or more phase shifters, the like, or any suitable combination thereof. Accordingly, the other circuitry 173 can include one or more radio frequency circuit elements. The other circuitry 173 can be referred to as radio frequency circuitry in certain applications. The other circuitry 173 can be electrically connected to the acoustic wave devices 174. The radio frequency module 170 can include one or more packaging structures to, for example, provide protection and/or facilitate easier handling of the radio frequency module 170. Such a packaging structure can include an overmold structure formed over the packaging substrate 176. The overmold structure can encapsulate some or all of the components of the radio frequency module 170.

FIG. 15 is a schematic block diagram of a module 200 that includes filters 202A to 202N, a radio frequency switch 204, and a low noise amplifier 206 according to an embodiment. One or more filters of the filters 202A to 202N can be implemented in accordance with any suitable principles and advantages disclosed herein. Any suitable number of filters 202A to 202N can be implemented. The illustrated filters 202A to 202N are receive filters. One or more of the filters 202A to 202N can be included in a multiplexer that also includes a transmit filter and/or another receive filter. The radio frequency switch 204 can be a multi-throw radio frequency switch. The radio frequency switch 204 can electrically couple an output of a selected filter of filters 202A to 202N to the low noise amplifier 206. In some embodiments, a plurality of low noise amplifiers can be implemented. The module 200 can include diversity receive features in certain applications.

FIG. 16 is a schematic diagram of a radio frequency module 210. As illustrated, the radio frequency module 210 includes diplexers 181A to 181N, a power amplifier 192, a radio frequency switch 194 configured as a select switch, and an antenna switch 182. The radio frequency module 210 can include a package that encloses the illustrated elements. The illustrated elements can be disposed on a common packaging substrate 217. The packaging substrate 217 can be a laminate substrate, for example. A radio frequency module that includes a power amplifier can be referred to as a power amplifier module. A radio frequency module can include a subset of the elements illustrated in FIG. 16 and/or additional elements.

The diplexers 181A to 181N can each include two acoustic wave filters coupled to a common node. For example, the two acoustic wave filters can be a transmit filter and a receive filter. As illustrated, the transmit filter and the receive filter can each be a band pass filter arranged to filter a radio frequency signal. Although FIG. 16 illustrates diplexers, any suitable principles and advantages disclosed herein can be implemented in other multiplexers (e.g., quadplexers, hexaplexers, octoplexers, etc.) and/or in switched multiplexers and/or with standalone filters.

The power amplifier 192 can amplify a radio frequency signal. The illustrated radio frequency switch 194 is a multi-throw radio frequency switch. The radio frequency switch 194 can electrically couple an output of the power amplifier 192 to a selected transmit filter of the transmit filters of the diplexers 181A to 181N. In some instances, the radio frequency switch 194 can electrically connect the output of the power amplifier 192 to more than one of the transmit filters. The antenna switch 182 can selectively couple a signal from one or more of the diplexers 181A to 181N to an antenna port ANT. The diplexers 181A to 181N can be associated with different frequency bands and/or different modes of operation (e.g., different power modes, different signaling modes, etc.).

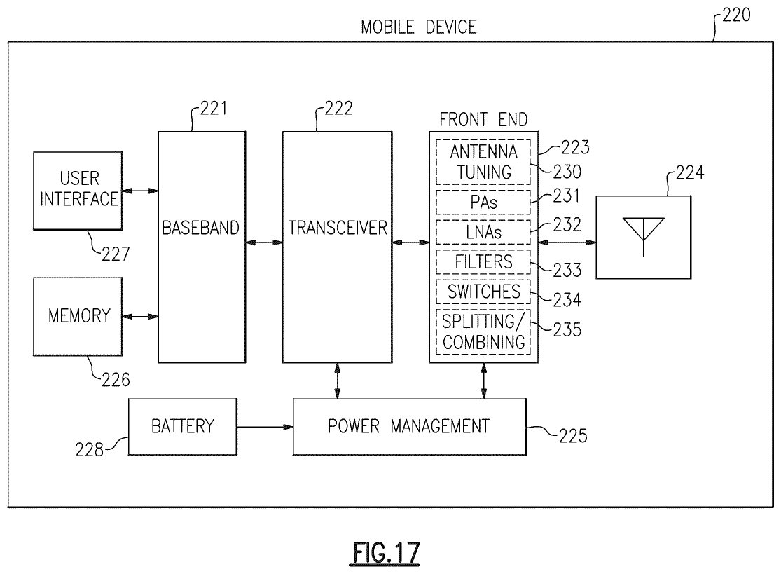

The extractors with a hybrid structure disclosed herein can be implemented in wireless communication devices. FIG. 17 is a schematic block diagram of a wireless communication device 220 that includes a extractors with a hybrid structure according to an embodiment. The wireless communication device 220 can be a mobile device. The wireless communication device 220 can be any suitable wireless communication device. For instance, a wireless communication device 220 can be a mobile phone, such as a smart phone. As illustrated, the wireless communication device 220 includes a baseband system 221, a transceiver 222, a front end system 223, one or more antennas 224, a power management system 225, a memory 226, a user interface 227, and a battery 228.

The wireless communication device 220 can be used to communicate using a wide variety of communications technologies, including, but not limited to, 2G, 3G, 4G (including LTE, LTE-Advanced, and/or LTE-Advanced Pro), 5G NR, WLAN (for instance, Wi-Fi), WPAN (for instance, Bluetooth and/or ZigBee), WMAN (for instance, WiMax), and/or GPS technologies.

The transceiver 222 generates RF signals for transmission and processes incoming RF signals received from the antennas 224. Various functionalities associated with the transmission and receiving of RF signals can be achieved by one or more components that are collectively represented in FIG. 17 as the transceiver 222. In one example, separate components (for instance, separate circuits or dies) can be provided for handling certain types of RF signals.

The front end system 223 aids in conditioning signals provided to and/or received from the antennas 224. In the illustrated embodiment, the front end system 223 includes antenna tuning circuitry 230, power amplifiers (PAS) 231, low noise amplifiers (LNAs) 232, filters 233, switches 234, and signal splitting/combining circuitry 235. However, other implementations are possible. The filters 233 can include one or more extractors with a hybrid structure in accordance with any suitable principles and advantages disclosed herein.

The front end system 223 can provide a number of functionalities, including, but not limited to, amplifying signals for transmission, amplifying received signals, filtering signals, switching between different bands, switching between different power modes, switching between transmission and receiving modes, duplexing of signals, multiplexing of signals, or any suitable combination thereof.

In certain implementations, the wireless communication device 220 supports carrier aggregation, thereby providing flexibility to increase peak data rates. Carrier aggregation can be used for Frequency Division Duplexing (FDD) and/or Time Division Duplexing (TDD), and may be used to aggregate a plurality of carriers and/or channels. Carrier aggregation includes contiguous aggregation, in which contiguous carriers within the same operating frequency band are aggregated. Carrier aggregation can also be non-contiguous, and can include carriers separated in frequency within a common band or in different bands.

The antennas 224 can include antennas used for a wide variety of types of communications. For example, the antennas 224 can include antennas for transmitting and/or receiving signals associated with a wide variety of frequencies and communications standards.

In certain implementations, the antennas 224 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The wireless communication device 220 can operate with beamforming in certain implementations. For example, the front end system 223 can include amplifiers having controllable gain and phase shifters having controllable phase to provide beam formation and directivity for transmission and/or reception of signals using the antennas 224. For example, in the context of signal transmission, the amplitude and phases of the transmit signals provided to the antennas 224 are controlled such that radiated signals from the antennas 224 combine using constructive and destructive interference to generate an aggregate transmit signal exhibiting beam-like qualities with more signal strength propagating in a given direction. In the context of signal reception, the amplitude and phases are controlled such that more signal energy is received when the signal is arriving to the antennas 224 from a particular direction. In certain implementations, the antennas 224 include one or more arrays of antenna elements to enhance beamforming.

The baseband system 221 is coupled to the user interface 227 to facilitate processing of various user input and output (I/O), such as voice and data. The baseband system 221 can include a baseband processor. The baseband system 221 provides the transceiver 222 with digital representations of transmit signals, which the transceiver 222 processes to generate RF signals for transmission. The baseband system 221 also processes digital representations of received signals provided by the transceiver 222. As shown in FIG. 17, the baseband system 221 is coupled to the memory 226 of facilitate operation of the wireless communication device 220.

The memory 226 can be used for a wide variety of purposes, such as storing data and/or instructions to facilitate the operation of the wireless communication device 220 and/or to provide storage of user information.

The power management system 225 provides a number of power management functions of the wireless communication device 220. In certain implementations, the power management system 225 includes a PA supply control circuit that controls the supply voltages of the power amplifiers 231. For example, the power management system 225 can be configured to change the supply voltage(s) provided to one or more of the power amplifiers 231 to improve efficiency, such as power added efficiency (PAE).

As shown in FIG. 17, the power management system 225 receives a battery voltage from the battery 228. The battery 228 can be any suitable battery for use in the wireless communication device 220, including, for example, a lithium-ion battery.

Technology disclosed herein can be implemented in filters with acoustic wave resonators in 5G applications. 5G technology is also referred to herein as 5G New Radio (NR). 5G NR supports and/or plans to support a variety of features, such as communications over millimeter wave spectrum, beamforming capability, high spectral efficiency waveforms, low latency communications, multiple radio numerology, and/or non-orthogonal multiple access (NOMA). Although such RF functionalities offer flexibility to networks and enhance user data rates, supporting such features can pose a number of technical challenges.

The teachings herein are applicable to a wide variety of communication systems, including, but not limited to, communication systems using advanced cellular technologies, such as LTE-Advanced, LTE-Advanced Pro, and/or 5G NR. A filter including any suitable combination of features disclosed herein can be arranged to filter a radio frequency signal in a 5G NR operating band within Frequency Range 1 (FR1). FR1 can be from 410 MHz to 7.125 GHz, for example, as specified in a current 5G NR specification. A filter in accordance with any suitable principles and advantages disclosed herein can be arranged to filter a radio frequency signal in a fourth generation (4G) Long Term Evolution (LTE). An acoustic wave filter in accordance with any suitable principles and advantages disclosed herein can have a pass band that includes a 4G LTE operating band and a 5G NR operating band. Such a filter can be implemented in a dual connectivity application, such as an E-UTRAN New Radio—Dual Connectivity (ENDC) application.

Filters with the extractor designs disclosed herein can have relatively wide passbands and also provide desirable out-of-band rejection. At the same time, the filters with the extractor designs disclosed herein can achieve relatively low insertion loss and desirable NF. Such features can be advantageous in 5G NR applications. Filters with the extractor designs disclosed herein can meet design specifications for one or more 5G NR operating bands that are challenging to meet with acoustic wave ladder filters.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “can,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While certain embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. A frequency extraction filter comprising:
a resonator coupled to a first node; and
a phase shifter connected to the resonator in parallel, the phase shifter coupled to a second node such that the resonator and the phase shifter are positioned between the first and second nodes, impedance between the first and second nodes has an order of five or more.

2. The frequency extraction filter of claim 1 wherein the impedance between the first and second nodes at least two notches for rejections.

3. The frequency extraction filter of claim 1 wherein the phase shifter is a passive phase shifter.

4. The frequency extraction filter of claim 3 wherein the passive phase shifter is a transmission line, a high pass network phase shifter, a low pass network phase shifter, an all pass network phase shifter, or a reflection type phase shifter.

5. The frequency extraction filter of claim 1 wherein the phase shifter is an active phase shifter.

6. The frequency extraction filter of claim 5 wherein the active phase shifter is a vector based phase shifter.

7. The frequency extraction filter of claim 1 wherein the impedance between the first and second nodes is controlled such that the phase shifter introduces at least one reflection zero and at least one transmission zero.

8. The frequency extraction filter of claim 7 wherein locations of the at least one transmission zero and the at least one reflection zero are set so as to improve insertion loss and rejection.

9. The frequency extraction filter of claim 1 wherein the resonator and the phase shifter together defines a first hybrid structure, and the frequency extraction filter further comprising a second resonator and a second phase shifter together defining a second hybrid structure, wherein the first and second hybrid structures are coupled to one another.

10. The frequency extraction filter of claim 9 further comprising a third resonator and a third phase shifter together defining a third hybrid structure, wherein the first, second, and third hybrid structures are electrically coupled.

11. The frequency extraction filter of claim 10 wherein the second resonator and the second phase shifter are connected in series, and the third resonator and the third phase shifter are connected in series.

12. A shunt hybrid extractor structure comprising:
a resonator coupled to a first node; and
a phase shifter connected to the resonator in parallel, the phase shifter coupled to a second node such that the resonator and the phase shifter are positioned between the first and second nodes, a frequency response of the shunt hybrid extractor structure includes at least three reflection zeros and at least two transmission zeros.

13. The shunt hybrid extractor structure of claim 12 wherein the phase shifter is a passive phase shifter.

14. The shunt hybrid extractor structure of claim 13 wherein the passive phase shifter is a transmission line, a high pass network phase shifter, a low pass network phase shifter, an all pass network phase shifter, or a reflection type phase shifter.

15. The shunt hybrid extractor structure of claim 12 wherein the phase shifter is an active phase shifter.

16. The shunt hybrid extractor structure of claim 15 wherein the active phase shifter is a vector based phase shifter.

17. A wireless communication device comprising:
a frequency extraction filter including a resonator coupled to a first node and a phase shifter connected to the resonator in parallel, the phase shifter coupled to a second node such that the resonator and the phase shifter are positioned between the first and second nodes, impedance between the first and second nodes has an order of five or more; and
an antenna coupled to the first node.

18. The wireless communication device of claim 17 wherein the resonator and the phase shifter together defines a first hybrid structure, and the frequency extraction filter further comprising a second resonator and a second phase shifter together defining a second hybrid structure, wherein the first and second hybrid structures are coupled to one another.

19. The wireless communication device of claim 18 further comprising a third resonator and a third phase shifter together defining a third hybrid structure, wherein the first, second, and third hybrid structures are electrically coupled.

20. The wireless communication device of claim 19 wherein the second resonator and the second phase shifter are connected in series, and the third resonator and the third phase shifter are connected in series.
